(19) United States
(12) Patent Application Publication
(10) Pub. No.: US 2025/0139757 A1
(43) Pub. Date: May 1, 2025

(54) METHOD OF INSPECTING A SEMICONDUCTOR PACKAGE

(71) Applicant: SAMSUNG ELECTRONICS CO., LTD., Suwon-si (KR)

(72) Inventors: Minwoo Jeon, Suwon-si (KR); Seunghwan Kim, Suwon-si (KR)

(21) Appl. No.: 18/754,533

(22) Filed: Jun. 26, 2024

(30) Foreign Application Priority Data
Nov. 1, 2023 (KR) 10-2023-0149277

(51) Int. Cl. G06T 7/00; G01N 21/95

(52) U.S. Cl. CPC G06T 7/0004; G01N 21/9501; G06T 2207/30148

(57) ABSTRACT

A method of inspecting a semiconductor package includes acquiring an image of a surface of a semiconductor package, classifying a characteristic of a mold bleed present on the surface of the semiconductor package and captured in the image, identifying that the mold bleed is abnormal, and generating an alarm upon identifying that the mold bleed is abnormal.

### CROSS-REFERENCE TO RELATED APPLICATION

This application is based on and claims priority under 35 U.S.C. § 119 to Korean Patent Application No. 10-2023-0149277, filed on Nov. 1, 2023, in the Korean Intellectual Property Office, the disclosure of which is incorporated by reference herein in its entirety.

### BACKGROUND

### 1. Technical Field

The inventive concept relates to a method of inspecting a semiconductor package, and more particularly, to a method of inspecting a semiconductor package for identifying and processing a mold bleed.

### 2. Discussion of Related Art

Semiconductor packages may be manufactured by implementing integrated circuit chips in a form appropriate for use in electronic products. In general, semiconductor packages may be manufactured by mounting semiconductor chips on printed circuit boards (PCBs) and electrically connecting the semiconductor chips to one another by using bonding wires or bumps. With recent developments in the electronics industry, semiconductor packages have been developed in various ways with the aim of miniaturization, weight reduction, and/or reduction of manufacturing costs. In addition, as the fields of application for the semiconductor packages expand to large-capacity storage units, various types of semiconductor packages have emerged. In particular, due to an increase in power consumption by high speed and high capacity semiconductor packages, the significance of thermal characteristics thereof has increased.

The heat dissipation characteristics of semiconductor packages may be improved by technologies that expose upper surfaces of semiconductor chips from molds that encapsulate the semiconductor chips. Here, mold bleed defects may occur in which a mold material may flow out to the upper surfaces of semiconductor chips during manufacturing processes, and the mold bleed defects may affect the heat dissipation characteristics of semiconductor packages.

### SUMMARY

The inventive concept provides a method of inspecting a semiconductor package, which may improve productivity of manufacture of a semiconductor package.

The objects of the inventive concept are not limited, and other objects not described herein may be clearly understood by one of ordinary skill in the art from the following description.

According to an aspect of the inventive concept, there is provided a method of inspecting a semiconductor package including acquiring an image of a surface of a semiconductor package, classifying a characteristic of a mold bleed present on the surface of the semiconductor package and captured in the image, identifying that the mold bleed is abnormal, and generating an alarm upon identifying that the mold bleed is abnormal.

According to another aspect of the inventive concept, there is provided a method of inspecting a plurality of semiconductor packages including acquiring images of surfaces of the plurality of semiconductor packages, classifying characteristics of mold bleeds present on the surfaces of the plurality of semiconductor packages and captured in the images, identifying that at least one of the mold bleeds is abnormal, and generating an alarm upon identifying that the at least one of the mold bleeds is abnormal.

According to another aspect of the inventive concept, there is provided a method of inspecting a semiconductor package including acquiring an image of a surface of the semiconductor package including a substrate, at least one semiconductor chip disposed on the substrate, a mold surrounding the semiconductor chip, and a mold bleed disposed on an upper surface of the semiconductor chip, classifying a characteristic of the mold bleed present on the upper surface of the semiconductor chip, the characteristic of the mold bleed including at least one of an area of the mold bleed or a generation type of the mold bleed, identifying that the mold bleed is abnormal, generating an alarm upon identifying that the mold bleed is abnormal, and mapping data about the mold bleed, wherein the generation type of mold bleed is classified according to at least one of a position of the mold bleed disposed on the upper surface of the semiconductor chip included in the semiconductor package, whether or not the mold bleed is present beyond a boundary defined by one or more of side surfaces of the semiconductor chip, or a planar shape of the mold bleed, and the identifying that the mold bleed is abnormal includes identifying, according to the area of the mold bleed, that the mold bleed is abnormal or identifying, according to the generation type of mold bleed, that the mold bleed is abnormal.

According to another aspect of the inventive concept, there is provided a method of inspecting a semiconductor package including acquiring an image of a surface of a semiconductor package, classifying a characteristic of a mold bleed present on the surface of the semiconductor package, identifying whether or not the mold bleed is abnormal, generating an alarm according to whether or not the mold bleed is abnormal, mapping data regarding whether or not the mold bleed is abnormal, and storing mapped data in a database. Accordingly, thermal and electrical characteristics of a semiconductor chip according to the characteristic of a mold bleed may be monitored, and thus, a quality of the semiconductor package may be identified. Further, productivity of manufacture of a semiconductor package may be improved.

### BRIEF DESCRIPTION OF THE DRAWINGS

Embodiments will be more clearly understood from the following detailed description taken in conjunction with the accompanying drawings in which:

FIG. 1 is a plan view illustrating a semiconductor package according to an embodiment;

FIG. 2 is a cross-sectional view taken along line A-A′ of FIG. 1;

FIG. 3 is a plan view illustrating a mold bleed generated in a semiconductor package;

FIG. 4 is a cross-sectional view taken along line B-B′ of FIG. 3;

FIG. 5 is a schematic flowchart illustrating a method of inspecting a semiconductor package, according to an embodiment;

FIG. 6 is a block diagram of an apparatus for inspecting a semiconductor package, according to an aspect of the present invention;

FIG. 7 is a view illustrating an operation of acquiring a surface image of a semiconductor package in a method of inspecting a semiconductor package, according to an aspect of the present invention;

FIG. 8 is a view illustrating a photograph of a surface image of a semiconductor package; and

FIG. 9 is a view illustrating an operation of mapping data regarding whether or not a mold bleed generated in the semiconductor package of FIG. 8 is abnormal.

### DETAILED DESCRIPTION

Hereinafter, embodiments will be described in detail with reference to the accompanying drawings. Like reference numerals refer to like elements, and their repetitive descriptions may be omitted.

The present disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the present disclosure. In the present disclosure, certain detailed descriptions may be omitted when they serve to obscure the essence of the inventive concept.

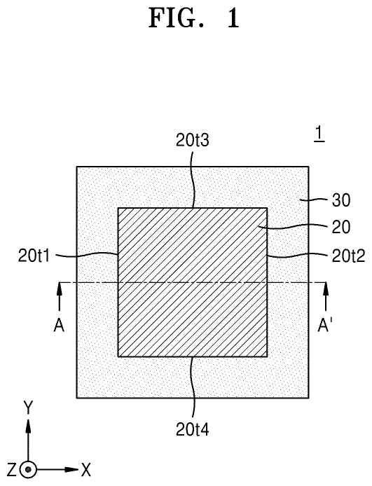

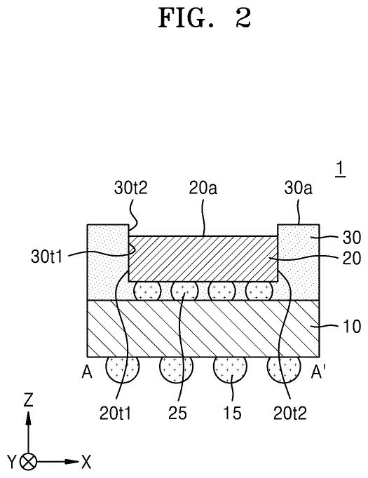

FIG. 1 is a plan view illustrating a semiconductor package according to an embodiment. FIG. 2 is a cross-sectional view taken along line A-A′ of FIG. 1. Hereinafter, a semiconductor package 1 to be inspected in a method of inspecting a semiconductor package is briefly described.

Referring to FIG. 1 and FIG. 2, the semiconductor package 1 may include a substrate 10, a semiconductor chip 20, and a mold 30.

The substrate 10 may include a package substrate such as a redistribution layer (RDL), an interposer, or a printed circuit board (PCB). Although not shown, the substrate 10 may include a single insulating layer or multilayer insulating layers. The substrate 10 may include wires within the insulating layer (e.g., a single insulating layer or multilayer insulating layers).

The insulating layer may include an insulating material. For example, the insulating layer may include silicon nitride, silicon oxide, silicon oxynitride, or a combination thereof. As another example, the insulating layer may include an organic material such as photosensitive polymer.

The photosensitive polymer may include, for example, at least one of photosensitive polyimide, polybenzoxazole, phenol-based polymer, or benzocyclobutene-based polymer. Alternatively, the photosensitive polymer may include a photo imageable dielectric (PID).

When the insulating layer is provided as multilayer insulating layers, the insulating layers may include a same material or different materials.

Each of the wires within the insulating layer may extend in a first horizontal direction X or a second horizontal direction Y. The wires may perform a function of redistributing and transmitting an electrical signal transmitted from outside the semiconductor package 1 or an electrical signal transmitted from the semiconductor chip 20. The wires may include a single layer or multiple layers.

In the description, unless otherwise stated, the first horizontal direction X may be defined as a direction parallel to an upper surface of the substrate 10, the second horizontal direction Y may be defined as a direction parallel to the upper surface of the substrate 10 and crossing the first horizontal direction X, and a vertical direction Z may be defined as a direction perpendicular to the upper surface of the substrate 10. For example, the second horizontal direction Y may be perpendicular to the first horizontal direction X.

Each of the wires may include a conductive material. For example, each of the wires may include metal such as copper (Cu), gold (Au), silver (Ag), aluminum (Al), tungsten (W), or titanium (Ti).

An external connection terminal 15 may be disposed at a lower surface of the substrate 10. For example, the external connection terminal 15 may be arranged on a lower surface of the substrate 10. The external connection terminal 15 may function as an electrical connection path between the semiconductor package 1 and an external device. A plurality of external connection terminals 15 may be provided. From a plan view, the external connection terminals 15 may be disposed in a two-dimensional arrangement.

The external connection terminal 15 may include, for example, at least one of a solder ball, a pillar, or a bump. The external connection terminal 15 may include a conductive metal material. The external connection terminal 15 may include, for example, at least one of tin (Sn), lead (Pb), nickel (Ni), gold (Au), silver (Ag), copper (Cu), aluminum (Al), or bismuth (Bi).

The semiconductor chip 20 may be disposed on the substrate 10. The semiconductor chip 20 may be implemented as any of various types of chips. For example, the semiconductor chip 20 may include a logic integrated circuit (IC), a dynamic random access memory (DRAM) chip, a micro component, an analog IC, an optical/sensor chip, a NAND flash chip, a ferroelectric random access memory (FRAM) chip, a resistive random access memory (RRAM) chip, a phase-change random access memory (PRAM) chip, or a magnetic random access memory (MRAM) chip.

The logic IC may include, for example, an application processor (AP), an application specific integrated circuit (ASAP), a central processing unit (CPU), a graphics processing unit (GPU), or a neural processing unit (NPU).

The micro component may include, for example, a micro processor unit (MPU), a micro controller unit (MCU), or a digital signal processor (DSP).

The analog IC may include, for example, a power management integrated circuit (PMIC) or a display driver integrated circuit (DDI).

The optical/sensor chip may include, for example, a complementary metal-oxide semiconductor (CMOS) image sensor (CIS).

As illustrated in FIG. 1, from a plan view, the semiconductor chip 20 may be arranged within the substrate 10. FIG. 1 and FIG. 2 illustrate one semiconductor chip 20, but a plurality of semiconductor chips 20 may be disposed on the substrate 10. The plurality of semiconductor chips 20 may be stacked in the vertical direction Z. Alternatively, the plurality of semiconductor chips 20 may be arranged in the first horizontal direction X or the second horizontal direction Y. For example, the plurality of semiconductor chips 20 may be disposed on the substrate 10 and the plurality of semiconductor chips 20 may be spaced apart from each other in the first horizontal direction X or the second horizontal direction Y.

When the plurality of semiconductor chips 20 are arranged on the substrate 10, the semiconductor chips 20 may include a same type of chip or may include different types of chips.

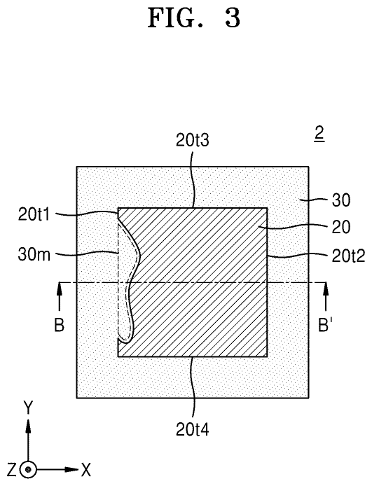

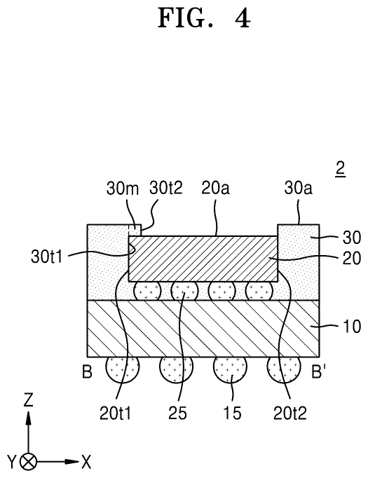

When the plurality of semiconductor chips 20 are stacked in the vertical direction Z, a mold bleed 30m illustrated in FIG. 3 and FIG. 4 may be generated on an upper surface 20a of the uppermost semiconductor chip 20. When the plurality of semiconductor chips 20 are spaced apart from each other in the first horizontal direction X or the second horizontal direction Y, the mold bleed 30m illustrated in FIG. 3 and FIG. 4 may be generated on the upper surface 20a of at least one of the plurality of semiconductor chips 20.

The semiconductor chip 20 may have a plurality of side surfaces. The semiconductor chip 20 may have a first side surface 20t1, a second side surface 20t2, a third side surface 20t3, and a fourth side surface 20t4. The first side surface 20t1, the second side surface 20t2, the third side surface 20t3, and the fourth side surface 20t4 may be the side surfaces of the semiconductor chip 20. The first side surface 20t1 and the second side surface 20t2 may be side surfaces facing each other in the first horizontal direction X. The third side surface 20t3 and the fourth side surface 20t4 may be side surfaces facing each other in the second horizontal direction Y.

A chip connection terminal 25 may be disposed on a lower surface of the semiconductor chip 20 and on the upper surface of the substrate 10. The chip connection terminal 25 may be disposed between the substrate 10 and the semiconductor chip 20. The chip connection terminal 25 may perform a function of electrically connecting the semiconductor chip 20 to the substrate 10.

The chip connection terminal 25 may include, for example, at least one of a solder ball, a pillar, or a bump. The chip connection terminal 25 may include a conductive metal material. The chip connection terminal 25 may include, for example, at least one of tin (Sn), lead (Pb), nickel (Ni), gold (Au), silver (Ag), copper (Cu), aluminum (Al), or bismuth (Bi).

The chip connection terminal 25 may be omitted. When the chip connection terminal 25 is omitted, the semiconductor chip 20 and the substrate 10 may be connected to each other by combining a metal pad arranged on the lower surface of the semiconductor chip 20 with a metal pad disposed on the upper surface of the substrate 10.

The chip connection terminal 25 may be provided, for example, when the semiconductor package 1 is formed through a chip last process. When the semiconductor package 1 is formed through a chip first process, the chip connection terminal 25 may be omitted.

The mold 30 may be disposed on the substrate 10. The mold 30 may cover the upper surface of the substrate 10. The mold 30 may surround the semiconductor chip 20. The mold 30 may cover the first side surface 20t1, the second side surface 20t2, the third side surface 20t3, and the fourth side surface 20t4 of the semiconductor chip 20. The mold 30 may surround the chip connection terminal 25. For example, a portion of the mold 30 may be disposed between the upper surface of the substrate 10 and the lower surface of the semiconductor chip 20.

A vertical level of an upper surface 30a of the mold 30 may be higher than a vertical level of the upper surface 20a of the semiconductor chip 20. The mold 30 may not cover the upper surface 20a of the semiconductor chip 20. Accordingly, the upper surface 20a of the semiconductor chip 20 may be exposed to the outside. The mold 30 may not cover the upper surface 20a of the semiconductor chip 20, and the upper surface 20a of the semiconductor chip 20 may be exposed to the outside. Internal heat generated by the semiconductor chip 20 may be diffused to the outside of the semiconductor package 1 via an exposed portion of the upper surface 20a of the semiconductor chip 20.

The mold 30 may include a plurality of inner sidewalls. The mold 30 may include a first inner sidewall 30t1 and a second inner sidewall 30t2. The first inner sidewall 30t1 and the second inner sidewall 30t2 may be portions of a same sidewall. For example, the first inner sidewall 30t1 may be a portion which is in contact with the semiconductor chip 20 and the second inner sidewall 30t2 may be a portion which is disposed higher than the upper surface 20a of the semiconductor chip 20.

In detail, the first inner sidewall 30t1 may be a portion which is in contact with the first side surface 20t1, the second side surface 20t2, the third side surface 20t3, and the fourth side surface 20t4 of the semiconductor chip 20.

The second inner sidewall 30t2 may be a portion which above from the first inner sidewall 30t1 and the upper surface 20a of the semiconductor chip 20. The second inner sidewall 30t2 may be a portion which extends from the first inner sidewall 30t1. The second inner sidewall 30t2 may be a portion which is disposed above the first side surface 20t1, the second side surface 20t2, the third side surface 20t3, and the fourth side surface 20t4. The second inner sidewall 30t2 may be a portion which is higher than the first side surface 20t1, the second side surface 20t2, the third side surface 20t3, and the fourth side surface 20t4. The mold 30 may include an insulating polymer such as an epoxy molding compound (EMC). The mold 30 may protect the semiconductor chip 20 from external environments.

As illustrated in FIG. 4, the first inner sidewall 30t1 and the second inner sidewall 30t2 may be separate sidewalls. For example, the first inner sidewall 30t1 may be a portion which is in contact with the semiconductor chip 20 and the second inner sidewall 30t2 may be a portion which is disposed on the upper surface 20a of the semiconductor chip 20.

In detail, the first inner sidewall 30t1 may be a portion which is in contact with the first side surface 20t1, the second side surface 20t2, the third side surface 20t3, and the fourth side surface 20t4 of the semiconductor chip 20.

The second inner sidewall 30t2 may be a portion which is disposed above the upper surface 20a of the semiconductor chip 20 and connected to the first inner sidewall 30t1 by a horizontal portion of the mold 30 at the mold bleed 30m disposed on the upper surface 20a of the semiconductor chip 20.

FIG. 3 is a plan view illustrating a mold bleed generated in a semiconductor package. FIG. 4 is a cross-sectional view taken along line B-B′ of FIG. 3. Hereinafter, a mold bleed 30m is described with reference to FIG. 3 and FIG. 4. A semiconductor package 2 of FIG. 3 and FIG. 4 may be substantially the same as the semiconductor package 1 in FIG. 1 and FIG. 2. Differences between the semiconductor package 2 may be mainly described. For simplicity of description, repetitive descriptions of the same components may be omitted.

FIG. 3 and FIG. 4 illustrate a mold 30 of the semiconductor package 2 extending onto an upper surface 20a of a semiconductor chip 20. A portion of the mold 30, which extends onto the upper surface 20a of the semiconductor chip 20, may be referred to as the mold bleed 30m.

The mold bleed 30m may be a portion that is continuously connected to a portion of the mold 30 or may be a portion that is spaced apart from a portion of the mold 30. The mold bleed 30m may be a portion vertically overlapping the semiconductor chip 20.

FIG. 3 and FIG. 4 illustrate that the mold 30 may extend onto the upper surface 20a of the semiconductor chip 20 in a first horizontal direction X. In other words, from a plan view, the mold bleed 30m may be generated beyond a boundary defined by a first side surface 20t1 of the semiconductor chip 20.

From a plan view, the mold bleed 30m may be generated beyond a boundary defined by any one of first side surface 20t1, the second side surface 20t2, the third side surface 20t3, and the fourth side surface 20t4. From a plan view, the mold bleed 30m may be generated beyond a boundary defined by two or more of the first side surface 20t1, the second side surface 20t2, the third side surface 20t3, and the fourth side surface 20t4. The mold bleed 30m may be spaced apart from the mold 30 and may be independently disposed on the upper surface 20a of the semiconductor chip 20. The mold bleed 30m may include a first portion generated beyond a boundary defined by any one of first side surface 20t1, the second side surface 20t2, the third side surface 20t3, and the fourth side surface 20t4 and a second portion independently disposed on the upper surface 20a of the semiconductor chip 20.

The mold bleed 30m may be a defect occurring due to any factor during a process of manufacturing the semiconductor package 2. When the mold bleed 30m is generated on the semiconductor chip 20, the mold bleed 30m may hinder the removal of heat generated by the semiconductor chip 20 and the emission of the heat to the outside.

The heat generated by the semiconductor chip 20 may remain inside the semiconductor chip 20 and may affect electrical characteristics of the semiconductor chip 20, such as an operating speed. After the semiconductor package 2 is manufactured, information regarding the mold bleed 30m may be identified, and thermal and electrical characteristics of the semiconductor chip 20 according to characteristics of the mold bleed 30m may be observed.

The characteristics of the mold bleed 30m may include, for example, the area and generation type of the mold bleed 30m. The area of the mold bleed 30m may be obtained by measuring a planar area of the mold bleed 30m disposed on the upper surface 20a of the semiconductor chip 20.

The generation type of mold bleed 30m may be classified, for example, according to a position of the mold bleed 30m disposed on the upper surface 20a of the semiconductor chip 20. For example, the generation type of mold bleed 30m may be classified according to whether or not the mold bleed 30m is generated beyond a boundary defined by one or more of the first side surface 20t1, the second side surface 20t2, the third side surface 20t3, and the fourth side surface 20t4.

For example, as illustrated in FIG. 3, when the mold bleed 30m is disposed beyond a boundary defined by the first side surface 20t1 of the semiconductor chip 20, the generation type of the mold bleed 30m may be an L-type. In the L type, L may be a moniker derived from the first letter of “Left” signifying left.

Similarly, when the mold bleed 30m is arranged beyond a boundary defined by any one of the second side surface 20t2, the third side surface 20t3, and the fourth side surface 20t4 of the semiconductor chip 20, the generation type of the mold bleed 30m may be classified into an R type, a T type, or a B type. In the R type, R may be a moniker derived from the first letter of “Right” signifying right. In the T type, T may be a moniker derived from the first letter of “Top” signifying top. In the B Type, B may be a moniker derived from the first letter of “Bottom” signifying bottom.

When the mold bleed 30m is generated beyond a boundary defined by two or more of the first side surface 20t1, the second side surface 20t2, the third side surface 20t3, and the fourth side surface 20t4, the generation type of mold bleed 30m may be defined by combining two or more of the letters “L”, “R”, “T”, and “B”. For example, when the mold bleed 30m is arranged beyond a boundary defined by the first side surface 20t1 and the third side surface 20t3, the generation type of the mold bleed 30m may be an LT type.

When the mold bleed 30m is independently disposed on a central portion of the upper surface 20a of the semiconductor chip 20, without a connection to at least one of the side surfaces, the generation type of mold bleed 30m may be a C type. In the C type, C may be a moniker derived from the first letter of “Center” signifying center.

The generation type of the mold bleed 30m may be classified into “L”, “R”, “T”, “B”, “C”, or a combination thereof. However, “L”, “R”, “T”, “B”, and “C” may be merely example monikers for describing the generation type of the mold bleed 30m. These monikers may be used relative to the view illustrated in FIG. 3. These monikers are not limiting and other terms may be used. A name or moniker defining the type of mold bleed 30m may be freely changed.

Classifying the generation type of mold bleed 30m according to the position of the mold bleed 30m disposed on the upper surface 20a of the semiconductor chip 20 is merely an example, and the generation type of the mold bleed 30m generated in the semiconductor package 2 may be classified according to various methods.

For example, the generation type of mold bleed 30m may be classified according to a planar shape of the mold bleed 30m. For example, the planar shape of the mold bleed 30m may be a polygonal shape, a circular shape, an elliptical shape, an annular shape, or an indeterminate form. The planar shape of the mold bleed 30m may be a dot shape in which several points are stamped. The planar shape of the mold bleed 30m may include various shapes.

From among various shapes of the mold bleed 30m, similar shapes may be classified into a category and defined using the generation types of mold bleed 30m. For example, when the planar shape of the mold bleed 30m is a circular shape, the generation type of mold bleed 30m may be a round type. Similarly, type monikers may be determined for other planar shapes of the mold bleed 30m, and the generation type of mold bleed 30m may be classified according to the type monikers.

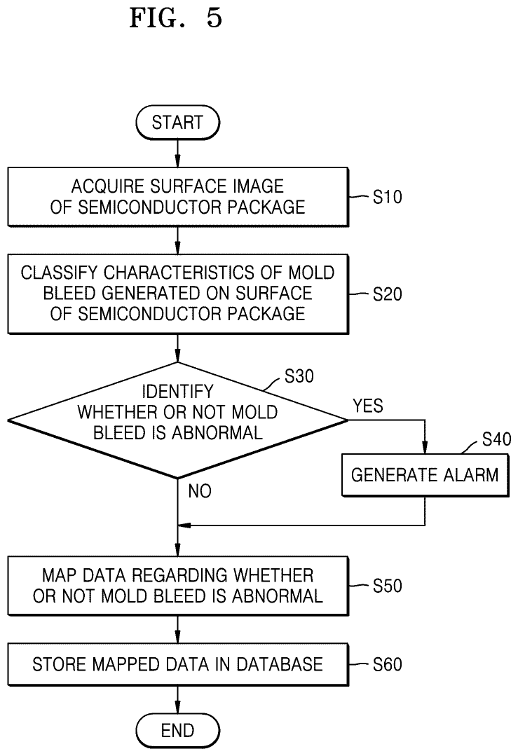

FIG. 5 is a schematic flowchart illustrating a method of inspecting a semiconductor package, according to an embodiment.

Referring to FIG. 5, a method of inspecting a semiconductor package may include: operation S10 of acquiring an image of a surface of the semiconductor package 1 or 2; operation S20 of classifying characteristics of the mold bleed 30m present on a surface of the semiconductor package 1 or 2 and captured in the image; operation S30 of identifying whether or not the mold bleed 30m is abnormal; operation S40 of generating an alarm according to whether or not the mold bleed 30m is abnormal; operation S50 of mapping data regarding whether or not the mold bleed 30m is abnormal; and operation S60 of storing the mapped data in a database. The operations of FIG. 5 may be performed in a different order then illustrated. The schematic flowchart is not limiting. For example, an alarm may be generated at operation S40 after the operation S60 of storing the mapped data in a database.

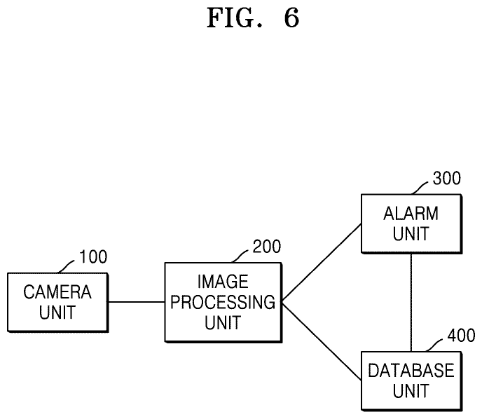

FIG. 6 is a block diagram of an apparatus for inspecting a semiconductor package, according to an aspect of the present invention.

Referring to FIG. 5 and FIG. 6, operation S10 of acquiring the image of the surface of the semiconductor package 1 or 2 may be performed by a camera unit 100.

Operation S20 of classifying the characteristics of the mold bleed 30m present on the surface of the semiconductor package 1 or 2 and captured in the image, and operation S30 of identifying whether or not the mold bleed 30m is abnormal may be performed by an image processing unit 200.

Operation S30 of identifying whether or not the mold bleed 30m is abnormal may be performed by an image processing unit 200 and may include identifying that the mold bleed 30m is one of normal or abnormal.

Operation S40 of generating the alarm according to whether or not the mold bleed 30m is abnormal may be performed by an alarm unit 300. Operation S50 of mapping the data regarding whether or not the mold bleed 30m is abnormal may be performed by the image processing unit 200.

Operation S60 of storing the mapped data in the database may be performed by a database unit 400.

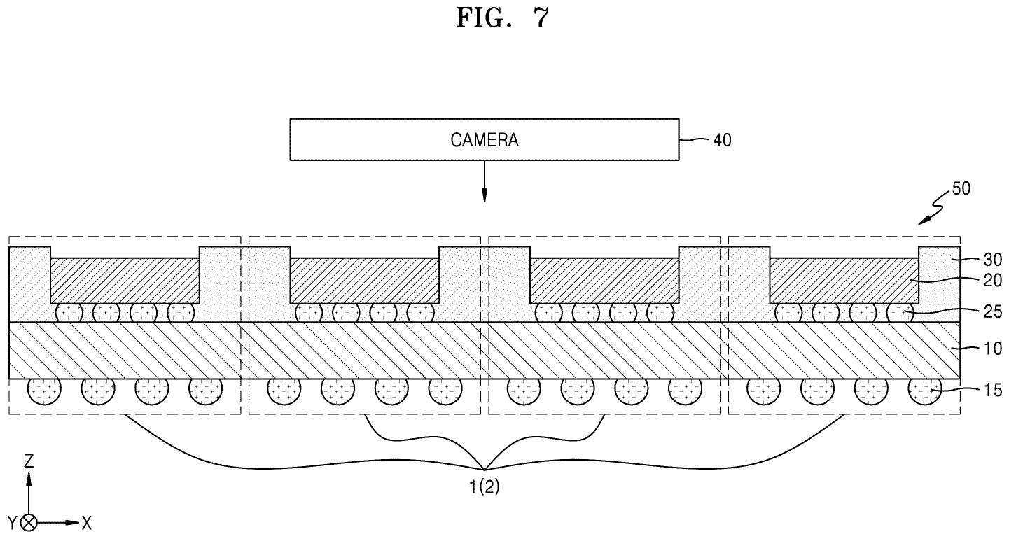

FIG. 7 is a view illustrating an operation of acquiring an image of a surface of a semiconductor package in a method of inspecting a semiconductor package, according to an aspect of the present invention.

Referring to FIG. 7, a camera 40 included in the camera unit 100 may photograph a package assembly 50. The package assembly 50 may include a plurality of semiconductor packages 1 and 2. The description of each of the plurality of semiconductor packages 1 and 2 may be the same as the description of the semiconductor package 1 in FIG. 1 and FIG. 2, or the semiconductor package 2 in FIG. 3 and FIG. 4. Hereinafter, the semiconductor packages 1 and 2 may be defined as including all the semiconductor packages 1 and 2 in which the mold bleed 30m is or is not generated.

FIG. 7 illustrates that the plurality of semiconductor packages 1 and 2 included in the package assembly 50 may share a substrate 10 and a mold 30. However, the plurality of semiconductor packages 1 and 2 included in the package assembly 50 may or may not share the substrate 10. Similarly, the plurality of semiconductor packages 1 and 2 included in the package assembly 50 may or may not share the mold 30.

The plurality of semiconductor packages 1 and 2 may be disposed in a first horizontal direction X or a second horizontal direction Y. FIG. 7 illustrates that the plurality of semiconductor packages 1 and 2 may be disposed in the first horizontal direction X.

A position of the camera 40 may be variously changed. The camera 40 may be arranged at any position at which the mold bleed 30m generated in the semiconductor packages 1 and 2 included in the package assembly 50 may be observed.

An image of the mold bleed 30m generated on the surface of each of the semiconductor packages 1 and 2 may be acquired by photographing a front side or surface of the package assembly 50 through the camera 40. Here, acquiring an image of the surface of the package assembly 50 may also be expressed as acquiring a surface image of the semiconductor packages 1 and 2. In addition, acquiring the image of the surface of the package assembly 50 may also be expressed as acquiring surface images of the plurality of semiconductor packages 1 and 2.

Here, the surface of each of the semiconductor packages 1 and 2 on which the mold bleed 30m may be generated may refer to the upper surface 20a of the semiconductor chip 20 included in each of the semiconductor packages 1 and 2. Therefore, an image of mold bleed 30m generated on the upper surface 20a of the semiconductor chip 20 may be acquired by photographing the front side or surface of the package assembly 50 through the camera 40.

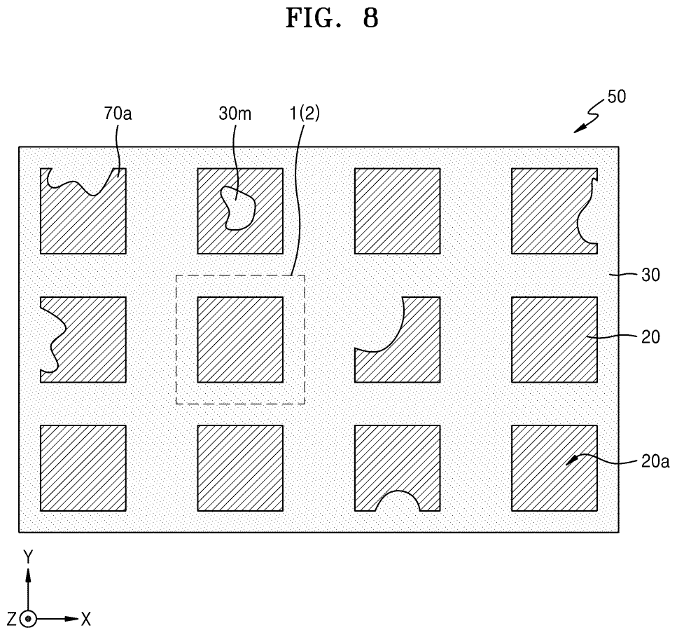

FIG. 8 is a view illustrating a photograph of a surface image of a semiconductor package.

FIG. 8 illustrates a photograph acquired by photographing a front side of a package assembly 50 through the camera 40 in FIG. 7. As described with reference to FIG. 7, the package assembly 50 may include a plurality of semiconductor packages 1 and 2. FIG. 8 may illustrate an image acquired in operation S10 of FIG. 5 of acquiring the surface image of the semiconductor package 1 or 2. As described with reference to FIG. 7, the plurality of semiconductor packages 1 and 2 may be disposed in a first horizontal direction X and/or a second horizontal direction Y. From a plan view, the plurality of semiconductor packages 1 and 2 may form a two-dimensional arrangement.

The package assembly 50 may include the semiconductor packages 1 and 2 in which the mold bleeds 30m are present and the semiconductor packages 1 and 2 in which the mold bleeds 30m are not present. In other words, some of the plurality of semiconductor packages 1 and 2 included in the package assembly 50 may have the mold bleeds 30m therein. In addition, other ones of the plurality of semiconductor packages 1 and 2 included in the package assembly 50 may not have the mold bleeds 30m.

The mold bleed 30m may be generated on an upper surface 20a of a semiconductor chip 20 included in each of the semiconductor packages 1 and 2. Here, in the surface image of each of the semiconductor packages 1 and 2 acquired through the camera 40, light and shade differences between the upper surface 20a of the semiconductor chip 20 and the mold bleed 30m may contrast each other. For example, the mold bleed 30m may be a relatively dark portion, and the upper surface 20a of the semiconductor chip 20 may be a relatively bright portion.

After acquiring the surface image of each of the semiconductor packages 1 and 2 as illustrated in FIG. 8, operation S20 of FIG. 5 of classifying the characteristics of the mold bleed 30m generated on the surface of the semiconductor package 1 or 2 may be performed.

As described with reference to FIG. 3 and FIG. 4, the characteristics of the mold bleed 30m may include an area and a generation type of the mold bleed 30m. Operation S20 of FIG. 5 of classifying the characteristics of the mold bleed 30m may include classifying the characteristics of the mold bleed 30m according to the area and the generation type of the mold bleed 30m.

The area of the mold bleed 30m may be obtained by measuring a planar area of the mold bleed 30m disposed on the upper surface 20a of the semiconductor chip 20. The area of the mold bleed 30m may be measured by using various methods.

For example, a method of measuring the area of the mold bleed 30m may include a method using distribution curves. For example, a first brightness distribution curve may be extracted for images of the upper surfaces 20a of the semiconductor chips 20 in which the mold bleed 30m is present, and a second brightness distribution curve may be extracted for images of the upper surfaces 20a of the semiconductor chips 20 in which the mold bleed 30m is not present.

Also, an average value and an allowed offset gray value may be extracted for the first brightness distribution curve and the second brightness distribution curve. An area of a mold bleed 30m may be classified by comparing a measured brightness of the upper surface 20a of the semiconductor chip 20 having the mold bleed 30m with the average values and the allowed offset gray values for the first brightness distribution curve and the second brightness distribution curve.

In another example, a method of measuring the area of the mold bleed 30m may include a method of using a gray value comparison method. A gray value comparison method may align, in ascending order, gray values for regions randomly partitioned on each of the upper surface 20a of the semiconductor chip 20 in which the mold bleed 30m is present and the upper surface 20a of the semiconductor chip 20 in which the mold bleed 30m is not present.

The area of the mold bleed 30m may be classified by comparing the gray values of each upper surface 20a of the semiconductor chips 20 with each other and determining each gray value satisfies a set range. For example, the set range may define a normal range in which the mold bleed 30m is not present. When the randomly partitioned regions are dense, the area of the mold bleed 30m may be accurately measured. Methods of measuring the area of the mold bleed 30m are merely examples and may be variously modified.

The generation type of mold bleed 30m may be classified, for example, according to a position of the mold bleed 30m disposed on the upper surface 20a of the semiconductor chip 20. A method of classifying the generation type of mold bleed 30m according to the position of the mold bleed 30m disposed on the upper surface 20a of the semiconductor chip 20 may be the same as described with reference to FIG. 3 and FIG. 4.

Alternatively, the generation type of mold bleed 30m may be classified on the basis of a planar shape of the mold bleed 30m. A method of classifying the generation type of mold bleed 30m according to the planar shape of the mold bleed 30m may be the same as described with reference to FIG. 3 and FIG. 4. However, a method of classifying the generation type of mold bleed 30m is an example and may be various modified.

The semiconductor chip 20 included in each of the semiconductor packages 1 and 2 may include various circuit elements. Here, from a plan view, types of circuit elements included in the semiconductor chip 20 may vary according to the positions thereof within the semiconductor chip 20. When the types of circuit elements vary, the amount of heat generated during an operation of the semiconductor chip 20 may vary.

Accordingly, the amount of heat generated from the semiconductor chip 20 may vary according to a planar position of the semiconductor chip 20. As a result, identifying the position of the mold bleed 30m generated on the upper surface 20a of the semiconductor chip 20 may be useful, for example, in determining a potential impact of the mold bleed 30m on heat transfer.

For example, a large amount of heat may be generated at a first position within the semiconductor chip 20, and the mold bleed 30m may be present at the first position. The first position may refer to a position from a plan view. Here, the mold bleed 30m present at the first position may function as an insulator, and heat may not easily escape from the inside of the semiconductor chip 20 to the outside due to. Here, the mold bleed 30m may have a large adverse effect on thermal and electrical characteristics of the semiconductor chip 20.

In contrast, a small amount of heat may be generated at a second position within the semiconductor chip 20, and the mold bleed 30m may be present at the second position. The second position may also refer to a position from a plan view. Here, while the mold bleed 30m present at the second position may function as an insulator, a reduction in the transfer of heat from the inside of the semiconductor chip 20 to the outside may be small due. Here, the mold bleed 30m may have a small effect on the thermal and electrical characteristics of the semiconductor chip 20.

In summary, an effect on operating characteristics of the semiconductor chip 20 may vary according to a generation position of the mold bleed 30m. Therefore, identifying the generation position of the mold bleed 30m may be useful.

The positions at which the mold bleed 30m is generated may be categorized, and the effect on the operating characteristics of the semiconductor chip 20 may be observed according to each type. Accordingly, a quality of the semiconductor packages 1 and 2 may be determined according to the mold bleed 30m.

Identifying the planar shape of the mold bleed 30m may be useful. For example, the planar shape of the mold bleed 30m may extend long in a horizontal direction. Alternatively, the planar shape of the mold bleed 30m may be a dot shape in which several points are stamped. However, the planar shape of the mold bleed 30m is an example and other characteristics may be used to categorize the mold bleed 30m.

Here, the planar shape of the mold bleed 30m may vary according to a type of defect in a manufacturing process. Therefore, when a particular planar shape of the mold bleed 30m generated on the upper surface 20a of the semiconductor chip 20 repeatedly appears, the repeated appearance of the particular planar shape of the mold bleed 30m may help infer a cause of a defect occurring in the manufacturing process or eliminate the defect.

Operation S30 of FIG. 5 of identifying an abnormal state in which the mold bleed 30m is present may be performed. Operation S30 of FIG. 5 of identifying whether or not the mold bleed 30m is abnormal may include identifying, according to characteristics of the mold bleed 30m, an abnormal state of the mold bleed 30m.

In detail, operation S30 of FIG. 5 of identifying whether or not the mold bleed 30m is abnormal may include identifying, according to the area and/or the generation type of mold bleed 30m, whether or not the mold bleed 30m is abnormal.

An abnormal state of the mold bleed 30m may be identified according to the characteristics of the mold bleed 30m. Whether or not the mold bleed 30m is abnormal may be identified, for example, by a ratio of the area of the mold bleed 30m to the total area of the upper surface 20a of the semiconductor chip 20. For example, when the ratio of the area of the mold bleed 30m to the total area of the upper surface 20a of the semiconductor chip 20 is greater than about 20%, the mold bleed 30m may be defined as abnormal.

As another example, an abnormal state of the mold bleed 30m may be identified according to the generation type of mold bleed 30m. For example, when the generation type of mold bleed 30m is the R type described with reference to FIG. 3 and FIG. 4, the mold bleed 30m may be classified as normal, and when the generation type of mold bleed 30m is the remaining L type, T type, and B type, the mold bleed 30m may classified as abnormal.

An abnormal state of the mold bleed 30m may be identified by combining the area and the generation type of the mold bleed 30m. For example, the area of the mold bleed 30m to the total area of the upper surface 20a of the semiconductor chip 20 may be greater than about 20%, but when the generation type of mold bleed 30m is the R type, the mold bleed 30m may be defined as normal.

Subsequently, operation S40 of FIG. 5 of generating the alarm according to whether or not the mold bleed 30m is abnormal may be performed. Operation S40 of generating the alarm may be performed upon identifying that the mold bleed 30m is abnormal in operation S30.

Operation S40 of FIG. 5 of generating the alarm may include, for example, displaying an alarm A or an alarm B. For example, when the ratio of the area of the mold bleed 30m to the total area of the upper surface 20a of the semiconductor chip 20 is X1% to X2%, the alarm may correspond to the alarm A. Here, X1 may be greater than or equal to about 0% and less than about 100%, and X2 may be greater than X1 and less than or equal to about 100%. X1 and X2 may be real numbers. In addition, when the ratio of the area of the mold bleed 30m to the total area of the upper surface 20a of the semiconductor chip 20 is X2% to about 100%, the alarm may correspond to the alarm B.

Expressed in particular numbers, when the ratio of the area of the mold bleed 30m to the total area of the upper surface 20a of the semiconductor chip 20 is about 20% to about 50%, about 30% to about 50%, or about 40% to about 50%, the alarm may correspond to the alarm A. A lower limit and an upper limit of the alarm A may be changed.

For example, when the ratio of the area of the mold bleed 30m to the total area of the upper surface 20a of the semiconductor chip 20 is greater than about 50%, the alarm may correspond to the alarm B. A lower limit of the alarm B may be changed.

The alarm A may refer to a state indicating that the mold bleed 30m may be abnormal or normal according to the generation type of mold bleed 30m and may vary. The alarm B may correspond to a state indicating that a degree of defect in the mold bleed 30m is more serious than in the alarm A and needing additional or a detailed diagnosis.

The alarms may also be classified into several types according to an area range of the mold bleed 30m. In addition, the alarm A being variable is an example, and the alarm A is not limited thereto. Like the alarm B, the alarm A may also correspond to a state that needs additional or a detailed diagnosis. The state of the alarm may vary according to a method of defining the state of the alarm by a user.

The alarm A and the alarm B may be different alarms. The alarm A and the alarm B may be expressed in any form, such as a text form, a color form, a sound form, or a combination thereof. For example, the alarm A may be displayed with “Fail”, and the alarm B may be displayed with “Outlier”. The alarm A and the alarm B may be expressed in any form that may be recognized by the user.

Due to operation S50 of FIG. 5 of generating the alarm, whether or not the mold bleed 30m is generated may be quickly and easily identified. Here, whether or not the semiconductor packages 1 and 2 are of high quality may be quickly and easily identified according to the characteristics of the mold bleed 30m, and thus, the time taken to inspect a semiconductor package may be reduced. As a result, productivity of the manufacture of the semiconductor packages 1 and 2 may be improved.

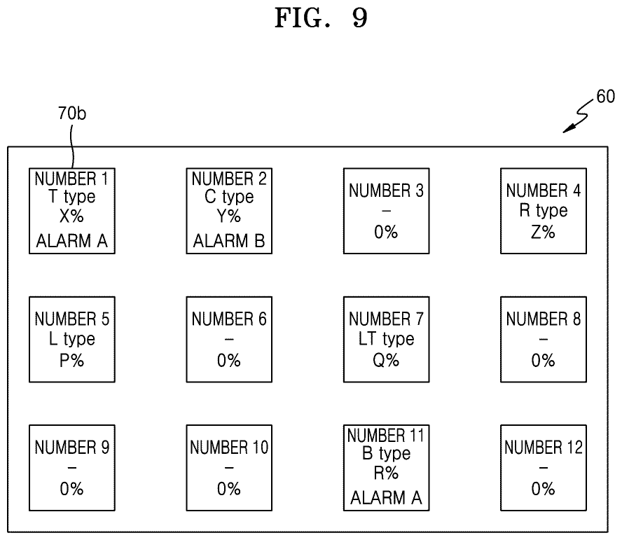

FIG. 9 is a view illustrating an operation of mapping data regarding whether or not a mold bleed generated in the semiconductor package of FIG. 8 is abnormal.

Referring to FIG. 9, operation S50 of FIG. 5 of mapping the data regarding whether or not the mold bleed 30m is abnormal may be performed. Mapped information may be displayed on a display device 60. The display device 60 may be a display such as a computer screen or a screen of semiconductor package equipment. However, the display device 60 is not limited thereto, and any device that may be recognized by a user may correspond to the display device 60.

Mapping data regarding whether or not the mold bleed 30m is abnormal may refer to displaying whether or not the mold bleed 30m is abnormal, with respect to each of the plurality of semiconductor packages 1 and 2 included in the package assembly 50. Here, displaying whether or not the mold bleed 30m is abnormal may be a concept that further includes displaying the characteristics (e.g., the area and generation type) of the mold bleed 30m generated in each of the semiconductor packages 1 and 2. In addition, displaying whether or not the mold bleed 30m is abnormal may be a concept that further includes displaying whether or not an alarm is generated with respect to each of the semiconductor packages 1 and 2. Here, the term “displaying” may refer to displaying on the display device 60 in a form that may be recognized by the user.

Semiconductor packages 1 and 2 respectively indicated by numbers 1 to 12 (e.g., “NUMBER 1”) in FIG. 9 may correspond to the semiconductor packages 1 and 2 arranged at the same positions in FIG. 8, respectively. For example, information regarding a semiconductor package 70a indicated by number 1 in FIG. 8 may correspond to information regarding a semiconductor package 70b indicated by number 1 in FIG. 9. The description of information regarding semiconductor package indicated by numbers 2 to 12 may be omitted.

Here, the information regarding the semiconductor package 70b indicated by number 1 may refer to the number of the semiconductor package 70a indicated by number 1 in FIG. 8, the characteristics of the mold bleed 30m, and/or information regarding an alarm, which may be displayed on the display device 60. The information regarding the semiconductor package 70b indicated by number 1 may refer to information indicating whether or not the mold bleed 30m is abnormal.

In the information regarding the semiconductor package 70b indicated by number 1, the number (number 1) of the semiconductor chip 20, a generation type (a T type) of mold bleed 30m, and an area X % of the mold bleed 30m may be displayed. The area of the mold bleed 30m may refer to a ratio of the area of the mold bleed 30m to the total area of the upper surface 20a of the semiconductor chip 20.

The information regarding the semiconductor package 70b indicated by number 1 may indicate that the number of the semiconductor package 70a indicated by number 1 in FIG. 8 is the number 1, the mold bleed 30m is generated beyond a boundary defined by an upper surface of the semiconductor chip 20 (see also the third side surface 20t3 in FIG. 1 and FIG. 3), and the area of the mold bleed 30m is X %. In addition, an alarm A, which is a type of alarm, may be displayed in the information regarding the semiconductor package 70b indicated by number 1. The description of the alarm A may be the same as the description of the alarm A described with reference to FIG. 8.

Similarly, the number of the semiconductor chip 20, the generation type of mold bleed 30m, the area of the mold bleed 30m, and the type of alarm may be displayed even in information regarding semiconductor packages indicated by number 2 to number 12. Here, even when not identifying whether or not the mold bleed 30m is abnormal, the generation type of mold bleed 30m may not be displayed.

When mapped as illustrated in FIG. 9, information such as the position, type, and area of the mold bleed 30m generated in the semiconductor packages 1 and 2 may be identified. In addition, information regarding which portion of the package assembly 50 of FIG. 8 the mold bleed 30m is likely to be generated at may be identified.

Subsequently, operation S60 of FIG. 5 of storing the mapped data in the database may be performed. Here, the mapped data may be stored in the database. The mapped data may be stored in the database and may include data about abnormal and/or normal examples of the mold bleed 30m.

On the basis of data stored in the database, thermal and electrical characteristics of the semiconductor chip 20 according to the characteristics of the mold bleed 30m may be monitored in the future. When an effect of a particular characteristic of the mold bleed 30m on the thermal and electrical characteristics of the semiconductor chip 20 is capable of being monitored, whether or not the semiconductor package 2 is of high quality may be identified.

While the inventive concept has been particularly shown and described with reference to embodiments thereof, it will be understood that various changes in form and details may be made therein without departing from the spirit and scope of the following claims.

What is claimed is:

1. A method of inspecting a semiconductor package, the method comprising:
acquiring an image of a surface of the semiconductor package;
classifying a characteristic of a mold bleed present on the surface of the semiconductor package and captured in the image;
identifying that the mold bleed is abnormal; and
generating an alarm upon identifying that the mold bleed is abnormal.

2. The method of claim 1, wherein the classifying of the characteristic of the mold bleed comprises classifying the characteristic of the mold bleed according to a generation type of mold bleed.

3. The method of claim 2, wherein the generation type of mold bleed is classified according to a position of the mold bleed disposed on an upper surface of a semiconductor chip included in the semiconductor package.

4. The method of claim 2, wherein a semiconductor chip included in the semiconductor package comprises a first side surface, a second side surface, a third side surface, and a fourth side surface, and
wherein the generation type of mold bleed is classified according to whether or not the mold bleed is present beyond a boundary defined by at least one of the first side surface, the second side surface, the third side surface, and the fourth side surface, from a plan view.

5. The method of claim 2, wherein the identifying that the mold bleed is abnormal comprises identifying, according to the generation type of mold bleed, that the mold bleed is abnormal.

6. The method of claim 2, wherein the generation type of mold bleed is classified according to a planar shape of the mold bleed disposed on an upper surface of a semiconductor chip included in the semiconductor package.

7. The method of claim 1, wherein the classifying of the characteristic of the mold bleed comprises classifying the characteristic of the mold bleed according to an area of the mold bleed.

8. The method of claim 7, wherein the identifying that the mold bleed is abnormal comprises identifying, according to an area of the mold bleed, that the mold bleed is abnormal.

9. The method of claim 8, wherein the generating of the alarm comprises generating an alarm A when the area of the mold bleed to a total area of an upper surface of a semiconductor chip included in the semiconductor package is X1% to X2%, and
wherein X1 is greater than or equal to 0 and less than 100, and X2 is greater than X1 and less than or equal to 100.

10. The method of claim 9, wherein the generating of the alarm further comprises displaying an alarm B when a ratio of the area of the mold bleed to the total area of the upper surface of the semiconductor chip is X2% or more, and
wherein the alarm A is different from the alarm B.

11. A method of inspecting a plurality of semiconductor packages, the method comprising:
acquiring images of surfaces of the plurality of semiconductor packages;
classifying characteristics of mold bleeds present on the surfaces of the plurality of semiconductor packages and captured in the images;
identifying that at least one of the mold bleeds is abnormal; and
generating an alarm upon identifying that the at least one of the mold bleeds is abnormal.

12. The method of claim 11, further comprising:
extracting data about the mold bleeds, wherein the data includes areas of the mold bleeds; and
mapping the data about the mold bleeds,
wherein the mapping comprises displaying the areas of the mold bleeds.

13. The method of claim 12, further comprising:
extracting data about the mold bleeds, wherein the data includes generation types of the mold bleeds; and
mapping the data about the mold bleeds,
wherein the mapping comprises displaying the generation types of the mold bleeds.

14. The method of claim 11, further comprising:
extracting data about the mold bleeds;
mapping the data about the mold bleeds; and
storing the data about the mold bleeds in a database.

15. The method of claim 11, further comprising:
extracting data about the mold bleeds; and
mapping the data about the mold bleeds,
wherein the mapping of the data comprises displaying an alarm generated in the generating of the alarm upon identifying that the at least one of the mold bleeds is abnormal.

16. The method of claim 11, wherein the generating of the alarm upon identifying that a first mold bleed of the mold bleeds is abnormal comprises generating an alarm A when a ratio of an area of the first mold bleed to a total area of an upper surface of a semiconductor chip including the first mold bleed is between X1% to X2%, and
wherein X1 is greater than or equal to 0 and less than 100, and X2 is greater than X1 and less than or equal to 100.

17. The method of claim 16, wherein the generating of the alarm upon identifying that the first mold bleed of the mold bleeds is abnormal further comprises generating an alarm B when a ratio of the area of the first mold bleed to the total area of the upper surface of the semiconductor chip including the first mold bleed is X2% or more, and
wherein the alarm A is different from the alarm B.

18. A method of inspecting a semiconductor package, the method comprising:
acquiring an image of a surface of the semiconductor package comprising a substrate, at least one semiconductor chip disposed on the substrate, a mold surrounding the semiconductor chip, and a mold bleed disposed on an upper surface of the semiconductor chip;
classifying a characteristic of the mold bleed on the upper surface of the semiconductor chip, the characteristic of the mold bleed comprising at least one of an area of the mold bleed or a generation type of the mold bleed;
identifying that the mold bleed is one of normal or abnormal;
generating an alarm upon identifying that the mold bleed is abnormal; and
mapping data about the mold bleed,
wherein the generation type of mold bleed is classified according to at least one of a position of the mold bleed disposed on the upper surface of the semiconductor chip included in the semiconductor package, whether or not the mold bleed is present beyond a boundary defined by one or more of side surfaces of the semiconductor chip, or a planar shape of the mold bleed, and
wherein the identifying that the mold bleed is abnormal comprises identifying, according to the area of the mold bleed, that the mold bleed is abnormal or identifying, according to the generation type of mold bleed, that the mold bleed is abnormal.

19. The method of claim 18, wherein the identifying that the mold bleed is abnormal further comprises identifying that the mold bleed is abnormal by combining the area of the mold bleed with the generation type of mold bleed.

20. The method of claim 18, wherein the mapping of the data about the mold bleed comprises displaying the area and the generation type of the mold bleed.
